(19) United States
(12) Patent Application Publication
(10) Pub. No.: US 2007/0240629 A1
(43) Pub. Date: Oct. 18, 2007

(54) Method for manufacturing a silicon single crystal

(75) Inventors: Toshirou Kotooka, Kanagawa (JP); Takashi Yokoyama, Kanagawa (JP); Kazuyoshi Sakatani, Kanagawa (JP); Toshiaki Saishoji, Kanagawa (JP); Koichi Shimomura, Kanagawa (JP); Ryota Suewaka, Kanagawa (JP)

Correspondence Address: BIRCH STEWART KOLASCH & BIRCH, PO BOX 747, FALLS CHURCH, VA, 22040-0747, US

(73) Assignee: SUMCO TECHXIV CORPORATION

(21) Appl. No.: 11/783,544

(22) Filed: Apr. 10, 2007

(30) Foreign Application Priority Data
Apr. 12, 2006 (JP) 2006-109642

(51) Int. Cl. C30B 15/00; C30B 27/02

(52) U.S. Cl. 117/13; 117/15; 117/30

(57) ABSTRACT

The present invention relates to a method for manufacturing a silicon single crystal by pulling up the silicon single crystal from a molten silicon by the CZ method, comprising: a cooling step of cooling the silicon single crystal by a cooler surrounding the silicon single crystal, and a heat shield body disposed surrounding an outer side and a lower side of the cooler while the silicon single crystal is being pulled up; and an Ms adjusting step of determining, in advance, an allowable range of a pulling speed at which a silicon single crystal having few crystal defects can be obtained by adjusting a distance (referred to “Ms”) from the lower surface of the heat shield body disposed on the lower side of the cooler to the surface of the molten silicon, wherein the silicon single crystal 11 is pulled up at a pulling speed within the allowable range thus determined.

This application is based on and claims the benefit of priority from Japanese Patent Application No. 2006-109642, filed on 12 Apr. 2006, the content of which is incorporated herein by reference.

### BACKGROUND OF THE INVENTION

1. Field of the Invention

The present invention relates to a method for manufacturing a silicon single crystal by the CZ method, and more particularly to a method for stably manufacturing a silicon single crystal having few crystal defects and a method for determining a stability condition thereof.

2. Related Art

A high-purity silicon single crystal (hereinafter abbreviated as “crystal” in some cases) is used in general for semiconductor device substrates, and the most widely-employed method for manufacturing it is the Czochralski method (hereinafter, referred to as “CZ method”). In a silicon single crystal manufacturing apparatus using the CZ method (CZ furnace), a self-rotating crucible 21 is installed at the center of a chamber 2 so that it can freely go up and down as shown in FIG. 1. The crucible 21 consists of a quartz crucible 21b housed in a graphite crucible 21a. Bulk polycrystalline silicon is loaded into the quartz crucible 21b, and the raw material is heated and melted by a cylindrical heater 22 arranged to surround the crucible 21, to produce molten silicon 13. Subsequently, a seed crystal attached to a seed holder 9 is dipped into the molten silicon 13, and the seed holder 9 is pulled upward while the seed holder 9 and the crucible 21 are rotated in the same or opposite directions from each other to let a silicon single crystal 11 grow so as to have a predetermined diameter and length.

In the process of manufacturing the silicon single crystal (single crystal ingot) by the above CZ method, crystal defects that may cause degradation of device characteristics occur in some cases during the growth of the silicon single crystal. These crystal defects become obvious in the process of manufacturing the device, which results in degradation of the device's performance.

It is generally thought that crystal defects include the following three kinds of defects.

### (1) Void (cavity) defects that are thought to occur as a result of aggregation of vacancies

### (2) Oxidation-induced stacking faults (OSF)

### (3) Dislocation cluster defects that are thought to occur as a result of aggregation of interstitial silicon

It is known that the manner in which these crystal defects occur varies as follows depending on the growth conditions.

### (1) When the growth speed of the crystal is high, the silicon single crystal will have excessive vacancies, and only void defects will occur.

### (2) When the growth speed becomes lower than that in the above case (1), ring-like OSFs will occur in the vicinity of the outer periphery of the silicon single crystal, and void defects will occur on the internal side of the OSF portion.

(3) When the growth speed becomes even lower than that in (2) above, the radius of the ring-like OSFs will be reduced, dislocation clusters will occur on the external side of the ring-like OSF portion, and void defects will occur on the internal side of the OSF portion.

### (4) When the growth speed becomes still lower than that in the above (3), dislocation cluster defects will occur throughout the entire silicon single crystal.

It is thought that the above phenomena occur because, with a decrease in the growth speed, the silicon single crystal changes its state from a state of excessive vacancies to a state of excessive interstitial silicon, and it is understood that the change starts at the outer periphery side of the silicon single crystal.

OSFs degrade the electrical characteristics; for example, they increase leak currents, and ring-like OSFs contain defects that cause such degradations of the characteristics in a high-density manner. Thus, in a normal process of manufacturing a silicon single crystal, the silicon single crystal is developed with a relatively high pulling speed so that the ring-like OSFs are distributed at the outermost rim of the silicon single crystal. By this method, the silicon single crystal mainly resides on the internal side of the ring-like OSF, which makes it possible to avoid the dislocation cluster defects. Further, the gettering effect against heavy-metal contamination occurring in the device manufacturing process is more significant on the internal side portion of the ring-like OSF than on the external peripheral side. Such a feature contributes to a reduction of the defects as well.

On the other hand, there has recently been a trend towards an increased degree of LSI integration, and as a result of this trend, since gate oxide films are becoming thinner, and the temperature in the device manufacturing process is lower, OSFs which readily occur in high-temperature processes tend to occur less frequently. In addition, there is a trend towards reduced oxygen in the crystal. Thus, OSFs such as ring-like OSFs have been less problematic as a factor which degrades device characteristics.

However, it is apparent that void defects occurring mainly in single crystals growing at high speed significantly degrade the pressure resistance characteristics of thinner gate oxide films. This impact is greater especially as device patterns become more precise, which will make it difficult to attempt a high degree of integration.

Therefore, in the recent manufacture of silicon single crystals, it has become more important to avoid void defects and dislocation cluster defects (hereinafter, defects including these defects shall be referred to as “grown-in defects” or “crystal defects”).

Conventionally, there have been various findings concerning manufacturing a crystal with no grown-in defects (below, referred to as “defect-free crystal”). For example, as for an axial direction temperature gradient in the vicinity of the solid-liquid interface at the silicon single central part of the crystal (below, referred to as “temperature gradient at the central part of the crystal) and an axial direction temperature gradient in the vicinity of the solid-liquid interface along the silicon single crystal side surface (hereinlater referred to as “temperature gradient along the side surface of the crystal”), it is generally known that a defect-free crystal can be manufactured by making the temperature gradient along the side surface of the crystal equal to or smaller than the temperature gradient at the central part of the crystal, viz., substantially equalizing an axial direction temperature gradient along the radius direction of the crystal in the vicinity of the solid-liquid interface. The term “temperature gradient at the central part of the crystal” used herein means a temperature gradient in a longitudinal direction at a center portion (crystal center line) 11a of the silicon single crystal 11, as shown in FIG. 5, and the term “temperature gradient along the side surface of the crystal” used herein means a temperature gradient in a longitudinal direction along a side surface 11b of the silicon single crystal 11, as shown in FIG. 5.

For equalizing the temperature gradient at the center portion of the silicon single crystal with the temperature gradient along the side surface of the crystal in a longitudinal direction, a method is known for decreasing a temperature gradient along the side surface of the crystal by, for example, adjusting the arrangement of constituent members in the furnace and the temperature distribution of the heater. This method, however, causes the pulling speed of the silicon single crystal to be decreased, thereby remarkably deteriorating the production efficiency of the silicon single crystal.

Thus, Japanese Patent No. 3573045 (hereinafter referred to as “Patent Document 1”) discloses a silicon single crystal manufacturing apparatus comprising a cooler 24 in order to enhance the pulling speed of the silicon single crystal (see FIG. 1). The cooler 24, however, plays a role only in enhancing the pulling speed of the silicon single crystal, but not in extending an allowable range of the pulling speed (width of the allowable range of the pulling speed) over which a silicon single crystal having few crystal defects can obtained. If the silicon single crystals are pulled up at a pulling speed out of the allowable range of the pulling speed, void defects or dislocation cluster defects will occur, and the rate of obtaining silicon single crystals of high quality deteriorates. If the allowable range of the pulling speed is extended, silicon single crystals of high quality can be manufactured stably even if there are fluctuations in the pulling speed. Therefore, it is difficult to manufacture a silicon single crystal having few crystal defects more stably unless the allowable range of the pulling speed is extended.

In order to overcome the above-mentioned drawback, according to the invention disclosed in Patent Document 1, the silicon single crystal manufacturing apparatus comprises a cooler 24 (see FIG. 1) and a heat shield body 23 (see FIG. 1), and, in addition, the arrangement and dimensions of the cooler 24, the extent (high/low) of the temperature at the central part and along the circumferential part of the silicon single crystal (side surface of the crystal), and the extent (large/small) of the temperature gradient at the central part and along the circumferential part of the silicon single crystal are defined within a predetermined temperature range, so as to equalize the temperature gradient at the central part of the crystal with the temperature gradient along the side surface of the crystal.

The invention disclosed in Patent Document 1, however, does not define a distance (below, referred to as “Ms”) from the lower surface of the heat shield body 23 disposed on the lower side of the cooler 24 to the surface of the molten silicon 13, which is indicative of an area where heat radiated from the quartz crucible 21b is dominant, although a distance (below, referred to as “Cs”) from the molten silicon 13 to the lower edge surface of the cooler 24 is defined.

### SUMMARY OF THE INVENTION

The present invention has been made to solve the foregoing problems, and it is an object of the present invention to provide a method for stably manufacturing a silicon single crystal having few silicon defects and a method for determining a stability condition thereof.

As a result of keen examination made by the present inventors to solve the foregoing problems, it has been found that an allowable range of the pulling speed can be extended by adjusting a distance (below, referred to as “Ms”) from a lower surface of the heat shield body disposed on the lower side of the cooler to a surface of the molten silicon, and thus, a silicon single crystal having few silicon defects can be manufactured stably. Specifically, the following is provided.

In accordance with a first aspect of the present invention, there is provided a method for manufacturing a silicon single crystal by pulling up the silicon single crystal from molten silicon by the CZ method, comprising: a cooling step of cooling the silicon single crystal by a cooler surrounding the silicon single crystal, and a heat shield body disposed surrounding an outer side and a lower side of the cooler while the silicon single crystal is being pulled up; and an Ms adjusting step of determining, in advance, an allowable range of a pulling speed over which a silicon single crystal having few crystal defects can be obtained by adjusting a distance (below, referred to “Ms”) from the lower surface of the heat shield body disposed on the lower side of the cooler to the surface of the molten silicon, and in which the silicon single crystal is pulled up at a pulling speed within the allowable range thus determined.

In order to stably manufacture a silicon single crystal having few crystal defects, the temperature gradient distribution in the axial direction along the radius direction of the crystal is required to be equalized. As an element to equalize the temperature gradient distribution in the axial direction along the radius direction of the crystal, the temperature gradient along the side surface of the crystal has been studied. It is thought that the temperature gradient along the side surface of the crystal is influenced at least by heat radiated from a surface of a crucible (for example, a quartz crucible 21b). Under the assumption that the heat radiated from the crucible surface can be controlled only by Ms, the invention disclosed in Patent Document 1 may not equalize the temperature gradient distribution in the axial direction along the radius direction of the crystal because the temperature gradient along the side surface of the crystal cannot be controlled fully. It is therefore difficult to conclude that the invention disclosed in Patent Document 1 makes it possible for a silicon single crystal having few crystal defects to be manufactured stably.

According to the first aspect of the present invention as previously mentioned, Ms, which had not been so far studied, is used as a parameter for determining the allowable range of a pulling speed over which a silicon single crystal having few crystal defects can be obtained (width of the allowable range of the pulling speed). This leads to the fact that conditions for most widely extending the allowable range of the pulling speed over which a silicon single crystal having few crystal defects can be obtained, that is, conditions for most stably manufacturing a silicon single crystal having few crystal defects, can be determined by adjusting Ms in advance to an optimum range.

A second aspect of the aforementioned method for manufacturing a silicon single crystal according to the present invention includes a step of adjusting the Ms in accordance with height of a solid-liquid interface at a crystal center when the silicon single crystal is pulled up.

The above-described allowable range of the pulling speed, outside of the Ms, is varied in accordance with the height of the solid-liquid interface at a crystal center when the silicon single crystal is pulled up. Therefore, the method according to the present invention as previously mentioned makes it possible to determine the conditions for most widely extending the allowable range of the pulling speed over which a silicon single crystal having few crystal defects can be obtained, that is, conditions for most stably manufacturing a silicon single crystal having few crystal defects.

A third aspect of the aforementioned method for manufacturing a silicon single crystal according to the present invention includes a representing an allowable range of a pulling speed, at which a silicon single crystal having few crystal defects can be obtained, by Vmax-Vmin, wherein Vmax is a pulling speed at which void defects occur and Vmin is a pulling speed at which dislocation cluster defects occur.

The defect distribution is changed as the pulling speed is lowered. In this case, the allowable range of the pulling speed can be estimated as a range from a pulling speed at which void type defects no longer occur, to a pulling speed at which dislocation cluster defects begin to occur. The method according to the third aspect of the present invention makes it possible to obtain a crystal having few crystal defects by restraining the allowable range to the above range.

A fourth aspect of the aforementioned method for manufacturing a silicon single crystal according to the present invention includes setting a width of the allowable range of a pulling speed, at which a silicon single crystal having few crystal defects can be obtained, to 0.04 mm/min or more.

Conventionally, it has been difficult to manufacture a silicon single crystal stably when the allowable range of the pulling speed is 0.04 mm/min or less, because a fluctuation width of the pulling speed needs to be reduced while the diameter of the silicon crystal is stabilized, thereby requiring a sophisticated temperature control.

The method according to the fourth aspect of the present invention, on the other hand, ensures that the allowable range of the pulling speed of 0.04 mm/min or more, and more preferably, up to approximately 0.07 mm/min is obtained. This allowable range is very advantageous in terms of the manufacturing technology, and it is possible to constantly supply silicon single crystals stable in product quality without variations in product quality.

A fifth aspect of the aforementioned method for manufacturing a silicon single crystal according to the present invention includes adjusting Ms so that it is a value 0.20D or more and 0.40D or less, wherein D is indicative of a diameter of the silicon single crystal to be pulled up.

According to the fifth aspect of the present invention, heat can be radiated appropriately from the surface of the molten silicon and the inner wall of the crucible on the side surface of the crystal by adjusting the Ms to a value 0.20D or more and 0.40D or less, thereby making it possible for a preferable temperature gradient along the side surface of the crystal to be generated.

A sixth aspect of manufacturing a silicon single crystal according to the present invention includes (a) setting an internal diameter of the cooler to a value 1.20D or more and 1.50D or less, (b) setting a length of the cooler along a pulling direction to 0.30D or more, (c) setting a distance (below, referred to as “Cs”) from a lower edge of the cooler to a surface of the molten silicon to a value 0.40D or more and 1.00D or less, (d) setting an internal diameter of the heat shield body member disposed surrounding the outer side of the cooler to a value 1.15D or more and 1.50D or less, and (e) setting the Ms to a value 0.20D or more and 0.40D or less, wherein D is indicative of a diameter of the silicon single crystal to be pulled up.

According to the sixth aspect of the present invention, the side surface of the crystal can be appropriately cooled by (a) setting the internal diameter of the cooler to a value 1.20D or more and 1.50D or less, and, in addition, an appropriate temperature gradient can be realized by (b) setting a length of the cooler along a pulling direction to 0.30D or more. Further, a temperature gradient can be appropriately realized such that a temperature gradient along the side surface of the crystal is equal to or smaller than a temperature gradient at the central part of the crystal by (c) setting a distance from the lower edge of the cooler to the surface of the molten silicon to a value 0.40D or more and 1.00D or less. Further, appropriate heat may be radiated from the surface of the molten silicon and the quartz crucible on the side surface of the crystal (d) setting the internal diameter of the heat shield body member disposed surrounding the outer side of the cooler to a value 1.15D or more and 1.50D or less, thereby enabling a more preferable temperature gradient to be generated on the surface of the crystal. Further, heat radiated from the surface of the molten silicon on the side surface of the crystal is made appropriate by (e) setting the Ms to at least 0.20D and at most 0.40D, wherein D is indicative of a diameter of the silicon single crystal to be pulled up, thereby enabling a more preferable temperature gradient to be generated on the surface of the crystal.

A seventh aspect of the aforementioned method for manufacturing a silicon single crystal according to the present invention includes, in the Ms adjusting step, adjusting a distance (below, referred to as “Ps”) from a lower surface of the cooler to an upper surface of the heat shield body disposed on the lower side of the cooler.

In the eighth aspect of the method for manufacturing a silicon single crystal according to the present invention, the Ps may be adjusted to 0.65D or less.

In a ninth aspect of the aforementioned method for manufacturing a silicon single crystal according to the present invention, the Ps may be adjusted to 0.45D or less.

The above-mentioned allowable range of the pulling speed is changeable in accordance with Ps, in addition to Ms. Therefore, in the method according to the seventh aspect of the present invention, a condition for most widely extending the allowable range of the pulling speed, that is, a condition for most stably manufacturing a silicon single crystal having few crystal defects can be determined. Preferably, the Ps is adjusted to 0.65D or less, and more preferably, Ps is adjusted to 0.45D or less, and especially preferably Ps is adjusted 0.2D or more and 0.4D or less.

In accordance with a tenth aspect of the present invention, a method is provided for determining an allowable range of a pulling speed at which a silicon single crystal having few crystal defects can be obtained when the silicon single crystal is pulled up from molten silicon by the CZ method while being cooled by a cooler surrounding the silicon single crystal, and a heat shield body disposed surrounding an outer side and a lower side of the cooler, by adjusting, in advance, a distance (below, referred to “Ms”) from a lower surface of the heat shield body disposed on the lower side of the cooler to a surface of molten silicon.

According to the tenth aspect of the present invention, the Ms plays a dominant role in determining an allowable range of a pulling speed at which a silicon single crystal having few crystal defects can be obtained. Therefore, conditions for most widely extending the allowable range of the pulling speed, that is, conditions for most stably manufacturing a silicon single crystal having few crystal defects can be determined by, in advance, adjusting the Ms to an optimum range.

In accordance with an eleventh aspect of the present invention, a method is provided for manufacturing a silicon single crystal by pulling up the silicon single crystal from molten silicon by the CZ method, comprising: a cooling step of cooling the silicon single crystal by a cooler surrounding the silicon single crystal, and a heat shield body disposed surrounding an outer side and a lower side of the cooler while the silicon single crystal is being pulled up, in which (a) an internal diameter of the cooler is set to a value 1.20D or more and 1.50D or less, (b) a length of the cooler along a pulling direction is set to 0.30D or more, (c) a distance from a lower edge of the cooler to a surface of the molten silicon is set to a value 0.40D or more and 1.00D or less, (d) an internal diameter of the heat shield body member disposed surrounding the outer side of the cooler is set to a value 1.15D or more and 1.50D or less, and (e) a distance from a lower surface of the heat shield body disposed on the lower side of the cooler to a surface of the molten silicon is set to a value 0.20D or more and 0.40D or less, wherein D is indicative of a diameter of the silicon single crystal to be pulled up.

According to the eleventh aspect of the present invention, the side surface of the crystal can be appropriately cooled because (a) an internal diameter of the cooler is set to a value 1.20D or more and 1.50D or less. An appropriate temperature gradient can be realized because (b) a length of the cooler along a pulling direction is set to 0.30D or more. Further, a temperature gradient can be realized appropriately in such a manner that a temperature gradient along the side surface of the crystal is equal to or smaller than a temperature gradient at the central part of the crystal because (c) a distance from the lower edge of the cooler to the surface of the molten silicon is set to a value 0.40D or more and 1.00D or less. Further, heat radiated from the surface of the molten silicon and the quartz crucible on the side surface of the crystal can be made appropriate because (d) the internal diameter of the heat shield body member disposed surrounding the outer side of the cooler is set to a value 1.15D or more and 1.50D or less, thereby enabling a more preferable temperature gradient to be generated on the surface of the crystal. Further, heat is appropriately radiated from the surface of the molten silicon on the side surface of the crystal because (e) the distance from the lower surface of the heat shield body disposed on the lower side of the cooler to the surface of the molten silicon is set to a value 0.20D or more and 0.40D or less, thereby enabling a more preferable temperature gradient to be generated on the surface of the crystal. Therefore, the aforementioned method according to the present invention increases the allowable range of the pulling speed, thereby enabling stable manufacture of the silicon single crystal having few crystal defects.

In accordance with the present invention, the allowable range of the pulling speed can be extended, thereby enabling stable manufacture of a silicon single crystal having few crystal defects.

### BRIEF DESCRIPTION OF THE DRAWINGS

The features and advantages of the method for manufacturing a silicon single crystal according to the present invention will more clearly be understood from the following description taken in conjunction with the accompanying drawings in which:

FIG. 1 is a cross-sectional view schematically showing a silicon single crystal manufacturing apparatus embodying the present invention;

FIG. 2 is a graph showing an allowable range of the pulling speed at which a silicon single crystal having few crystal defects can be obtained;

FIG. 3 is a graph showing the change in the allowable range of the pulling speed of a silicon single crystal having few crystal defects where the height of the solid-liquid interface is shown on the horizontal axis, and Ms is shown on the vertical axis;

FIG. 4 is a graph showing the change of the allowable range of the pulling speed of the silicon single crystal having few crystal defects where Ps is shown on the horizontal axis, and Ms is shown on the vertical axis;

FIG. 5 is a fragmentary sectional view illustrating “temperature gradient at the central part of the crystal” and “temperature gradient along the side surface of the crystal”;

FIG. 6 is a table showing conditions according to the present invention under which the silicon single crystal is pulled up;

FIG. 7 is a table showing specific examples of the conditions shown in FIG. 6 under which the silicon single crystal is pulled up; and

FIG. 8 is a table showing pulling speeds of the silicon single crystals and allowable ranges of the pulling speed of the silicon single crystal having few crystal defects, through comparative examples.

### DETAILED DESCRIPTION OF THE INVENTION

The present invention will be described in detail with reference to the drawings.

### Overview of a Silicon Single Crystal Manufacturing Apparatus

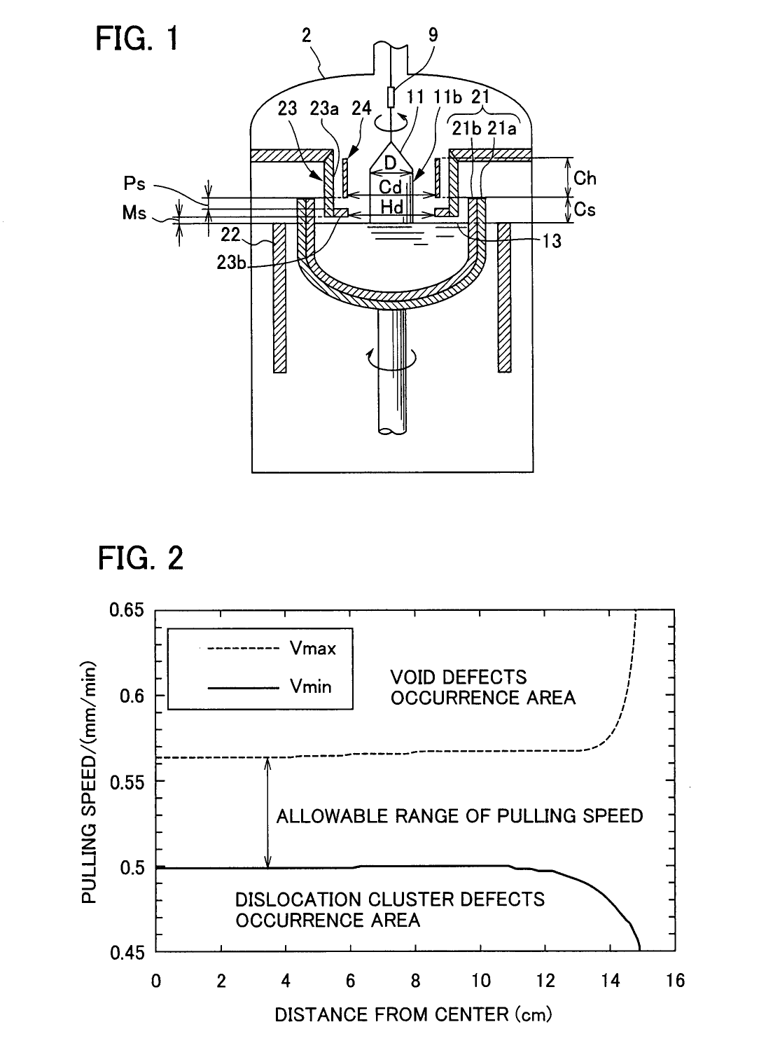

A preferred embodiment of a silicon single crystal manufacturing apparatus (CZ furnace) will be described first with reference to FIG. 1. As shown in FIG. 1, the silicon single crystal manufacturing apparatus comprises a self-rotating crucible 21 disposed at the center of a chamber 2 so that it can freely go up and down as a hot zone configuration. The crucible 21 consists of a quartz crucible 21b housed in a graphite crucible 21a. Bulk polycrystalline silicon is loaded into the quartz crucible 21b, and the raw material is heated and melted by a cylindrical heater 22 provided surrounding the crucible 21 to produce molten silicon 13. Subsequently, a seed crystal attached to a seed holder 9 is dipped into the molten silicon 13, and the seed holder 9 is pulled upward while the seed holder 9 and the crucible 21 are rotated in the same or opposite directions from each other to let a silicon single crystal 11 grow so as to have predetermined diameter and length.

Also, the hot zone configuration of the CZ furnace includes a heat shield body (heat shield plate) 23 surrounding the silicon single crystal 11 rotated and pulled up from the molten silicon 13 and adjusting the amount of heat radiated onto the silicon single crystal 11, and a cooler 24 for cooling a side surface 11b of the silicon single crystal 11. It is noted that a solenoid may be provided in the hot zone configuration to apply a magnetic field to the molten silicon 13 in the hot zone configuration, so as to control the oxygen concentration in the silicon single crystal. In addition, providing the solenoid enables controlling convection of the molten silicon 13, thereby making it possible for the entire silicon single crystal 11 to be developed stably, as well as for dopant and impurity elements to be homogenized. Further, a magnetic field in a horizontal direction and a cusped magnetic field may be applied to the molten silicon 13.

The heat shield plate 23 is generally constituted of a carbon member and is adapted to control the temperature of the side surface 11b of the silicon single crystal 11 by shielding the radiant heat from the molten silicon 13. Also, the cooler 24 is installed surrounding the silicon single crystal 11 similarly to the heat shield plate 23. The cooler 24 is made of a metal material having a high heat conductivity such as, for example, copper, stainless steel, molybdenum, or the like, or a combination thereof, and has a cooling water flowing therethrough. The above-mentioned heat shield body 23 is disposed on the outer side and the lower side of the cooler 24. The silicon single crystal 11 is cooled by the cooler 24 and the heat shield body 23.

### Influence of Heat Radiated from Quartz Crucible Surface

A method is discussed for manufacturing a silicon single crystal having few crystal defects stably. As described above, in order to stably manufacture a silicon single crystal having few crystal defects, the temperature gradient distribution in the axial direction along the radius direction of the crystal should be equalized so that an allowable range of a pulling speed (width of the allowable range of the pulling speed) at which a silicon single crystal having few crystal defects can be obtained, needs to be extended. Meanwhile, the “allowable range of the pulling speed over which a silicon single crystal having few crystal defects can be obtained” means a range defined by Vmax-Vmin wherein Vmax is a pulling speed at which void defects occur and Vmin is a pulling speed at which dislocation cluster defects occur, as shown in FIG. 2.

Conventionally, in order to extend the allowable range of the pulling speed, the temperature gradient at the central part of the crystal and the temperature gradient along the side surface of the crystal are equalized by installing the cooler 24 in the silicon single crystal manufacturing apparatus (see FIG. 1), and furthermore, a distance (below, referred to as “Cs”) is defined from the lower edge (lower surface) of the cooler 24 to the surface of the molten silicon 13.

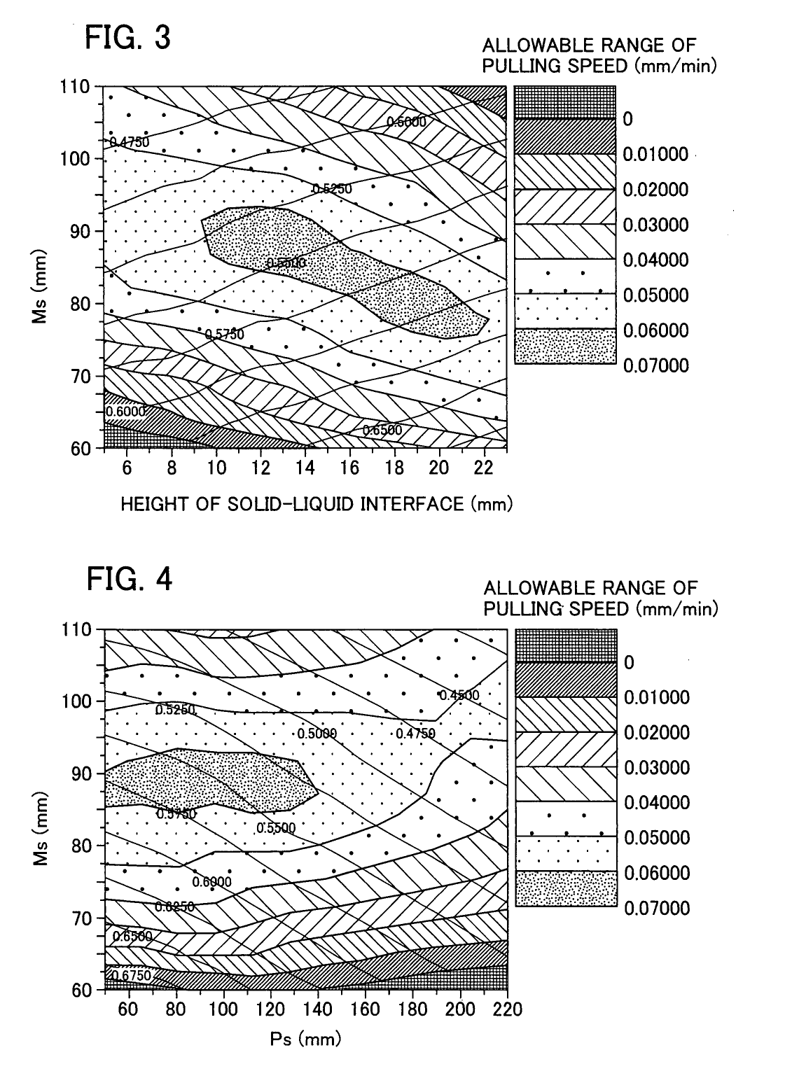

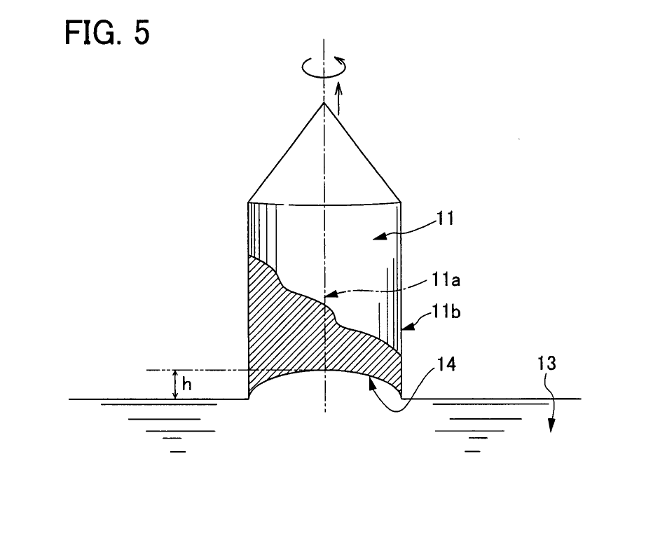

However, the present inventors considered that not only the cooling of the silicon single crystal 11 by means of the cooler 24, but also heat radiated from the surface of the quartz crucible 21b plays an important role in equalizing the temperature gradient distribution in the axial direction along the radius direction of the crystal. Further, the present inventors considered that the amount of heat radiated from the surface of quartz crucible 21b can be controlled by adjusting a distance (below, referred to as “Ms”) from the lower surface (lower edge) of the heat shield body 23 to the surface of the molten silicon 13, and thus, the amount of heat radiated on the side surface of the crystal can be controlled, thereby enabling extension of the allowable range of the pulling speed of the silicon single crystal having few crystal defects 11. The present inventors examined changes in the allowable range of the pulling speed of the silicon single crystal when the height of the solid-liquid interface and Ms are changed, as will be seen from FIG. 3. FIG. 3 shows the change of the allowable range of the pulling speed of the silicon single crystal having few crystal defects when a silicon single crystal having a diameter of 300 mm was manufactured using the silicon single crystal manufacturing apparatus shown in FIG. 1 under a condition where the height of the solid-liquid interface is shown on the horizontal axis, and Ms is shown on the vertical axis. Here, the length of the cooler 24 was set to 300 mm, and a distance (below, referred to as “Ps”) from the lower surface of the cooler 24 to the upper surface of the heat shield body 23 disposed on the lower side of the cooler 24 was fixed to 120 mm.

### Relationship between Ms and Allowable Range of Pulling Speed

As shown in FIG. 3, the allowable range of the pulling speed of the silicon single crystal having few crystal defects is changed in accordance with Ms and the height of the solid-liquid interface. That is, the allowable range of the pulling speed of the silicon single crystal having few crystal defects can be determined by adjusting Ms and the height of the solid-liquid interface.

Specifically, the allowable range of the pulling speed of the silicon single crystal having few crystal defects can be made 0.04 mm/min or more, by setting the height of the solid-liquid interface to a value 5 mm or more and less than 8 mm, and Ms to a value 77 mm or more and less than 110 mm, setting the height of the solid-liquid interface to a value 8 mm or more and less than 11 mm, and Ms to a value 75 mm or more and less than 105 mm, setting the height of the solid-liquid interface to a value 11 mm or more and less than 14 mm, and Ms to a value 72 mm or more and less than 103 mm, setting the height of the solid-liquid interface to a value 14 mm or more and less than 17 mm, and Ms to a value 69 mm or more and less than 101 mm, setting the height of the solid-liquid interface to a value 17 mm or more and less than 20 mm, and Ms to a value 67 mm or more and less than 98 mm, or setting the height of the solid-liquid interface to a value 20 mm or more and less than 23 mm, and Ms to a value 63 mm or more and less than 94 mm.

Next, the present inventors studied whether or not there is a parameter other than Ms which enables the allowable range of the pulling speed of the silicon single crystal having few crystal defects to be extended, and considered that the allowable range of the pulling speed of the silicon single crystal having few crystal defects can be extended by adjusting Ps as shown in FIG. 4, as will be described below. FIG. 4 shows the change of the allowable range of the pulling speed of the silicon single crystal having few crystal defects when a silicon single crystal having a diameter of 300 mm was manufactured using the silicon single crystal manufacturing apparatus shown in FIG. 1 under the condition where Ps is shown on the horizontal axis, and Ms is shown on the vertical axis. Here, the length of the cooler 24 was set to 300 mm, and height of the solid-liquid interface was fixed to 11 mm.

### Relationship between Ps and Allowable Range of Pulling Speed

As shown in FIG. 4, the allowable range of the pulling speed of the silicon single crystal having few crystal defects tends to be narrowed as Ps is increased. This may be because, when the cooler 24 is disposed too far from the solid-liquid interface, the effect by the cooler 24 of increasing the pulling speed of the silicon single crystal-11 is reduced. Therefore, Ps is preferably set to 200 mm or less (0.65D or less wherein the diameter of the silicon single crystal 11 is represented by D), and more preferably set to 140 mm or less (0.45D or less wherein the diameter of the silicon single crystal 11 is represented by D), in order to extend the allowable range of the pulling speed of the silicon single crystal having few crystal defects.

Specifically, the allowable range of the pulling speed of the silicon single crystal having few crystal defects can be made 0.04 mm/min or more, by setting Ps to a value 50 mm or more and less than 140 mm, and Ms to a value 72 mm or more and less than 105 mm, or setting Ps to a value 140 mm or more and less than 220 mm and Ms to a value 74 mm or more and less than 110 mm.

### Numerical Limitation of the Configuration of the Silicon Crystal Manufacturing Apparatus

As shown in FIG. 1, the configuration of the present embodiment is defined as follows, wherein the diameter of the silicon single crystal 11 is represented by D, the internal diameter of the cooler 24 is represented by Cd, the length of the cooler 24 along the pulling direction is represented by Ch, the distance from the lower edge (lower surface) of the cooler 24 to the surface of the molten silicon 13 is represented by Cs, the internal diameter of the heat shield body 23 is represented by Hd, the distance from the lower edge of the heat shield body 23 to the surface of the molten silicon 13 is represented by Ms, and the distance from the lower edge (lower surface) of the cooler 24 to the upper surface of the heat shield body disposed on the lower side of cooler 24 is represented by Ps.

### (1) Cd: 1.20D or more and 1.50D or less

### (2) Ch: 0.30D or more

### (3) Cs: 0.40D or more and 1.00D or less

### (4) Hd: 1.15D or more and 1.50D or less

### (5) Ms: 0.20D or more and 0.40D or less

### (6) Ps: 0.65D or less

Grounds for these limitations will be described below. Cd, which is the internal diameter of the cooler 24, is preferably set to a value 1.20D or more and 1.50D or less, wherein the diameter of the silicon single crystal 11 is represented by D. The internal diameter of the cooler 24 is defined in proportion to the diameter of the silicon single crystal 11 because the single crystallization cannot be confirmed when the internal diameter of the cooler 24 is disposed extremely close to the silicon single crystal 11 to the degree that the internal diameter of the cooler 24 is below 1.20D, and the cooling effect, on the other hand, becomes insufficient when the internal diameter of the cooler 24 is disposed too far from the silicon single crystal 11 to the extent that the internal diameter of the cooler 24 is beyond 1.50D.

The cooler 24 has an internal surface facing the silicon single crystal 11. The internal surface of the cooler 24 is rotationally symmetric with respect to an axis along which the single crystal is pulled up, and may be in the form of a cylindrical shape extending in a substantially parallel relationship with an outer surface of the silicon single crystal 11 as shown in FIG. 1. However, the internal surface of the cooler 24 may be in the form of a variant shape as long as the internal diameter of the internal surface facing the silicon single crystal 11 is a value 1.20D or more and 1.50 or less. The internal surface may be in the form of, for example, a stepped shape such that the internal surface of the lower portion is less in terms of the internal diameter than that of the higher portion, or an inverted truncated cone shape such that the higher the internal surface is located, the more the internal diameter of the internal surface is increased. The internal surface having the minimum internal diameter is preferably located at a lower edge portion in the vicinity of the molten silicon surface in the case where the internal surface is in the form of such a variant shape, Ch indicative of the length of the cooler 24 along the pulling direction is preferably set to 0.30D or more. This is because, when Ch is set to less than 0.30, the effect of embodying the required temperature gradient cannot be obtained.

Cs indicative of the distance from the lower edge (lower surface) of the cooler 24 to the surface of the molten silicon 13 is preferably set to 0.40D or more and 1.00D or less. This is because, when Cs is less than 0.40D, the temperature gradient of the side surface of the crystal becomes too large and thus an equalized temperature gradient distribution in the axial direction of the crystal cannot be obtained. Further, when Cs is more than 1.00D, the silicon single crystal 11 immediately after being solidified cannot be sufficiently cooled, thereby making it difficult to obtain the effects of the cooler 24 to increase the axial direction temperature gradient in the vicinity of the crystal interface, to increase the pulling speed and to extend the allowable range of the silicon single crystal 11.

The heat shield body 23 includes a heat shield body member 23a disposed between an outer side surface of the cooler 24 and an inner wall of the crucible 21 and a heat shield body member 23b disposed between a lower edge side of the cooler 24 and the surface of the molten silicon 13. The heat shield body 23 thus constructed prevents the cooling effect by the cooler 24 from reaching unnecessary portions of the apparatus, facilitates obtaining a required temperature distribution, and prevents the cooler 24 from being heated. A fire-resistant material including graphite, carbon felt, ceramic, or any combination thereof is used as the heat shield body members 23a and 23b.

The internal diameter Hd of the heat shield body member 23b disposed between the lower edge side of the cooler 24 and the surface of the molten silicon 13 is set to a value 1.15D or more and 1.50D or less. When Hd is less than 1.15D, the crystal and the heat shield body member 23b may be brought into contact, in cases where the crystal is deformed. When, on the other hand, Hd is more than 1.5D, both the effect of the radiation from the quartz to equalize the temperature gradient in the surface of the crystal and the effect by the cooler 24 to increase the axial direction temperature gradient as a whole cannot be expected at the same time, thereby making it difficult to obtain an equalized temperature gradient distribution in the axial direction along the radius direction of the crystal.

Ms, which is the distance from the lower surface of the heat shield body 23 to the surface of the molten silicon 13, is preferably set to a value 0.20D or more and 0.40D or less. This is because when Ms is less than 0.20D, heat radiated from the surface of the molten silicon 13 and the inner wall of the crucible 21 (specifically, from the quartz crucible 21b) on the side surface of the crystal immediately after being solidified, is decreased, and thus the temperature gradient along the side surface of the crystal becomes far larger than the temperature gradient at the central part of the crystal, thereby making it difficult to obtain an appropriate temperature gradient. When, on the other hand, Ms is more than 0.40D, heat radiated from the surface of the molten silicon 13 and the inner wall of the crucible 21 on the side surface of the crystal is increased, and thus the temperature gradient along the side surface of the crystal becomes far smaller than the temperature gradient at the central part of the crystal, thereby making it difficult to obtain an appropriate temperature gradient.

Ps indicative of the distance from the lower surface of the cooler 24 to the upper surface of the heat shield body 23 disposed on the lower side of cooler 24 is preferably set to 0.65D or less, and more preferably, set to 0.45D or less. When the cooler 24 is disposed distant from the surface of the molten silicon 13, the effect by the cooler 24 of increasing the axial direction temperature gradient in the vicinity of the crystal interface, cannot be expected, thereby making it difficult to extend the allowable range of the pulling speed at which a silicon single crystal having few crystal defects can be obtained. This means that the effect by the cooler 24 of increasing the axial direction temperature gradient in the vicinity of the crystal interface cannot be expected unless Ps is set to 0.65D or less. Further, the axial direction temperature gradient can be further increased when Ps is set to 0.45 or less.

In order to have the entire single crystal in a state with extremely few grown-in defects when the single crystal is manufactured using the single crystal manufacturing apparatus comprising the above-mentioned cooling member and heat shield body, the single crystal is required to be pulled up at an optimum speed over which a defect free area can be extended. This optimum speed is strongly influenced by heat state of the entire apparatus as well as material, shape, and construction of each of the cooling member and the heat shield body. Therefore, it is preferable to select an optimum pulling speed by pulling up a test single crystal with a pulling speed gradually changed while the test single crystal is being developed, cutting the resulting test single crystal along the pulling axis, and studying the distribution of the defects on the longitudinal section, to pull a single crystal at the optimum speed thus selected.

An example of the present invention will be described below. A silicon single crystal 11 having a diameter of 300 mm was pulled up using the silicon single crystal manufacturing apparatus schematically shown in FIG. 1.

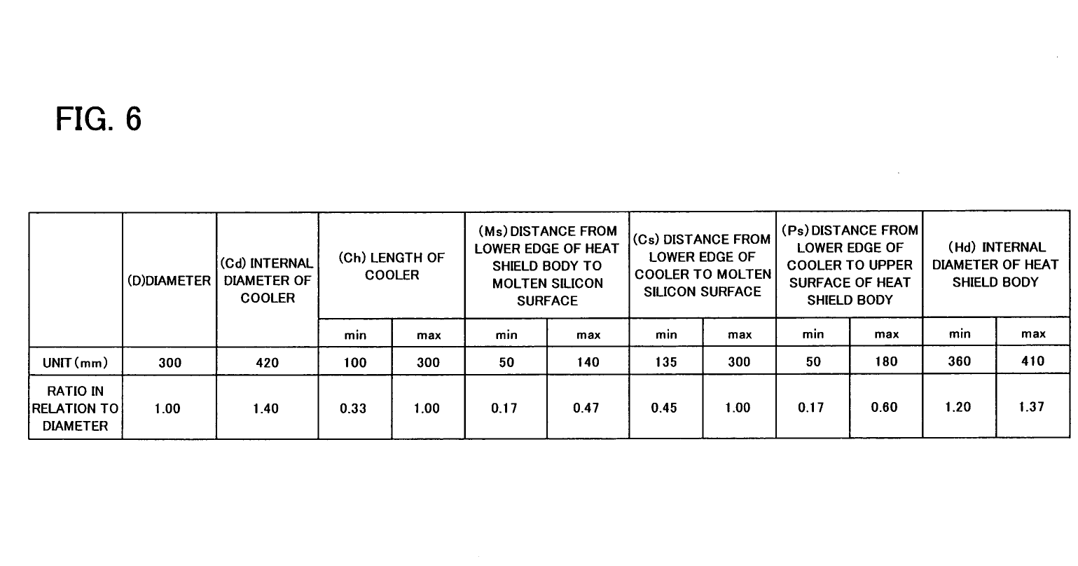

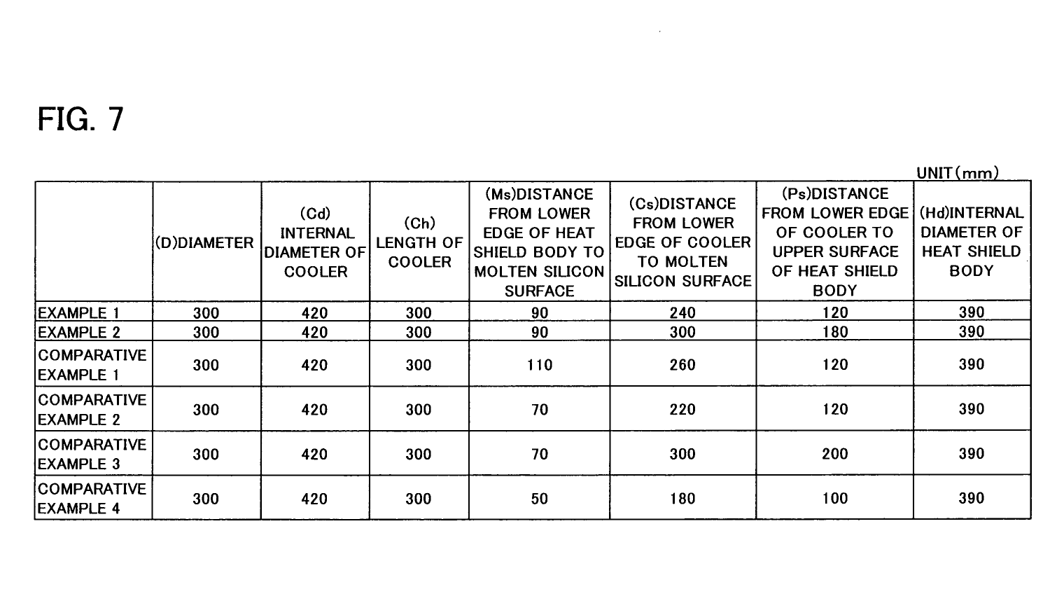

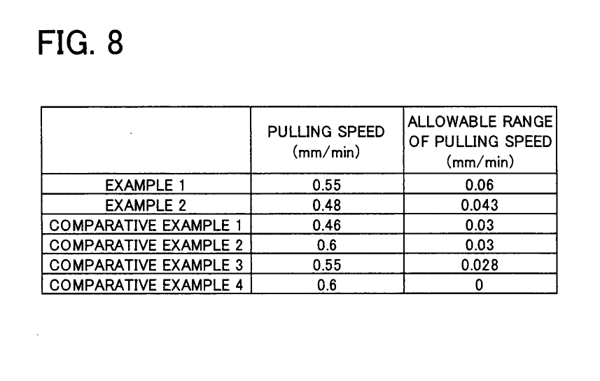

FIG. 6 is a table showing conditions under which the silicon single crystal 11 was pulled up, that is, the internal diameter of the cooler 24, the length of the cooler, Ps, Cs, internal diameter of the heat shield body 23, and Ms. FIG. 7 is a table showing specific examples of the conditions under which the silicon single crystal 11 was pulled up shown in FIG. 6 (examples 1 and 2). FIG. 8 is a table showing the pulling speed of the silicon single crystal 11 and the allowable range of the pulling speed of the silicon single crystal having few crystal defects in the above examples.

### COMPARATIVE EXAMPLES

The silicon single crystal 11 was pulled up under the same conditions as the above examples except for Ms, Cs, and Ps as shown in FIG. 7 (comparative examples 1 through 4). FIG. 8 shows, through the above comparative examples, the pulling speed of the silicon single crystal 11 and the allowable range of the pulling speed of the silicon single crystal having few crystal defects.

As shown in FIG. 8, it is apparent that the pulling speed of the silicon crystal 11 can be enhanced and also that the allowable range of the pulling speed of the silicon single crystal having few crystal defects is extended in examples 1 and 2, in comparison with the comparative examples. As will be seen from the foregoing, it is to be understood that a silicon single crystal having few crystal defects can be manufactured stably under the pulling conditions of the examples, in comparison with the pulling conditions of the comparative examples.

While preferred embodiments of the present invention have been described and illustrated above, it is to be understood that they are exemplary of the invention and are not to be considered to be limiting. Additions, omissions, substitutions, and other modifications can be made thereto without departing from the spirit or scope of the present invention. Accordingly, the invention is not to be considered to be limited by the foregoing description and is only limited by the scope of the appended claims.

What is claimed is:

1. A method for manufacturing a silicon single crystal by pulling up the silicon single crystal from molten silicon by the CZ method, comprising:
a cooling step of cooling the silicon single crystal by a cooler surrounding the silicon single crystal, and a heat shield body disposed surrounding an outer side and a lower side of the cooler, while the silicon single crystal is being pulled up; and
an Ms adjusting step of determining, in advance, an allowable range of a pulling speed at which a silicon single crystal having few crystal defects can be obtained by adjusting a distance, referred to as “Ms”, from the lower surface of the heat shield body disposed on the lower side of the cooler, to the surface of the molten silicon; wherein
the silicon single crystal is pulled up at a pulling speed within the allowable range thus determined.

2. A method for manufacturing a silicon single crystal according to claim 1, wherein
in the Ms adjusting step the Ms is adjusted in accordance with a height of a solid-liquid interface at a crystal center when the silicon single crystal is pulled up.

3. A method for manufacturing a silicon single crystal according to claim 1, wherein
in the Ms adjusting step the allowable range of a pulling speed over which a silicon single crystal having few crystal defects can be obtained, is expressed by Vmax-Vmin, where Vmax is a pulling speed at which void defects occur and Vmin is a pulling speed at which dislocation cluster defects occur.

4. A method for manufacturing a silicon single crystal according to claim 1, wherein
in the Ms adjusting step a width of the allowable range of a pulling speed at which a silicon single crystal having few crystal defects can be obtained, is set to at least 0.04 mm/min.

5. A method for manufacturing a silicon single crystal according to claim 1, wherein
In the Ms adjusting step Ms is adjusted to a value of at least 0.20D and at most 0.40D, in which D is a diameter of the silicon single crystal to be pulled up.

6. A method for manufacturing a silicon single crystal according to claim 1, wherein the Ms adjusting step comprising
(1) setting an internal diameter of the cooler to a value of at least 1.20D and at most 1.50D,
(2) setting length of the cooler along a pulling direction to a value of at least 0.30D,
(3) setting a distance, referred to as “Cs”, from a lower edge of the cooler to a surface of the molten silicon to a value of at least 0.40D and at most 1.00D,
(4) setting an internal diameter of the heat shield body member disposed surrounding the outer side of the cooler to a value of at least 1.15D and at most 1.50D, and
(5) setting the Ms to a value of at least 0.20D and at most 0.40D, wherein
D is indicative of a diameter of the silicon single crystal to be pulled up.

7. A method for manufacturing a silicon single crystal according to claim 1, wherein
the Ms adjusting step comprises adjusting a distance, referred to as “Ps”, from a lower surface of the cooler to an upper surface of the heat shield body disposed on the lower side of the cooler.

8. A method for manufacturing a silicon single crystal according to claim 7, wherein
the Ps is adjusted to at most 0.65D.

9. A method for manufacturing a silicon single crystal according to claim 7, wherein
the Ps is adjusted to a value of at most 0.45D.

10. A method for determining an allowable range of a pulling speed at which a silicon single crystal having few crystal defects can be obtained when the silicon single crystal is pulled up from molten silicon by the CZ method, while being cooled by a cooler surrounding the silicon single crystal, and a heat shield body disposed surrounding an outer side and a lower side of the cooler, by adjusting, in advance, distance, referred to “Ms”, from a lower surface of the heat shield body disposed on the lower side of the cooler to a surface of molten silicon

11. A method for manufacturing a silicon single crystal by pulling up the silicon single crystal from molten silicon by the CZ method, comprising: a cooling step of cooling the silicon single crystal by a cooler surrounding the silicon single crystal, and a heat shield body disposed surrounding an outer side and a lower side of the cooler while the silicon single crystal is being pulled up, wherein
(1) an internal diameter of the cooler is set to a value of at least 1.20D and at most 1.50D,
(2) a length of the cooler along a pulling direction is set to a value of at least 0.30D,
(3) a distance from a lower edge of the cooler to a surface of the molten silicon is set to a value of at least 0.40D and at most 1.00D,
(4) an internal diameter of the heat shield body member disposed surrounding the outer side of the cooler is set to a value of at least 1.15D and at most 1.50D, and
(5) a distance from a lower surface of the heat shield body disposed on the lower side of the cooler to a surface of the molten silicon is set to a value of at least 0.20D and at most 0.40D, and wherein
D is indicative of a diameter of the silicon single crystal to be pulled up.
